(19) United States
(12) Patent Application Publication
(10) Pub. No.: US 2011/0165456 A1
(43) Pub. Date: Jul. 7, 2011

(54) ELECTRONIC DEVICE AND BATTERY WHICH CAN BE USED FOR ELECTRONIC DEVICE

(75) Inventor: Masakazu NAKAMURA, Tokyo (JP)

(73) Assignee: KABUSHIKI KAISHA TOSHIBA, Tokyo (JP)

(21) Appl. No.: 12/796,848

(22) Filed: Jun. 9, 2010

(30) Foreign Application Priority Data
Jan. 4, 2010 (JP) 2010-000041

(51) Int. Cl. H01M 2/30; H05K 5/00

(52) U.S. Cl. 429/178; 361/679.01

(57) ABSTRACT

An electronic device configured to alternatively accommodate one of a first battery and a second battery is provided. The electronic device has a housing in which a battery holder including a first space and a second space is formed. The first space is shaped so as to hold the first battery. The second space continues from the first space. The second space is narrower than the first space at an interface between the first space and the second space. The second space is shaped so that the first space and the second space can hold the second battery together. The electronic device has a contact terminal for supplying the electronic device with power from one of the first battery and the second battery. The contact terminal is provided in the first space.

### CROSS REFERENCE TO RELATED APPLICATIONS

This application is based upon and claims the benefit of priority from the prior Japanese Patent Application No. 2010-41 filed on Jan. 4, 2010;

the entire contents of which are incorporated herein by reference.

### FIELD

The present invention relates to an electronic device which can use batteries of different capacities, and to a battery which can be used for the electronic device.

### BACKGROUND

Some portable electronic device accommodates a chargeable battery of high power density so as to be supplied with necessary driving power even where no commercial power is supplied. If the electronic device is used and the battery power decreases, the battery is charged so that the battery power is recovered.

Incidentally, a period of time in which to recharge the battery depends upon the total number of hours of driving the electronic device and a capacity of the battery. Thus, it is desirable that the electronic device be designed to use plural batteries of different capacities in accordance with a user's way to use the device.

It is ordinarily known that some electronic device is designed to use batteries of different thicknesses, i.e., one of three sizes (length, width and thickness) of a battery.

Such an ordinary electronic device, however, particularly a mobile phone or a data terminal required to be thin or small and loaded with a large-sized battery, is inevitably uneasy to handle. Further, in order that the length or width of the three sizes of the battery is changed and that batteries of different sizes are used, it is difficult to fix and support the batteries by means of a common mechanism.

### BRIEF DESCRIPTION OF THE DRAWINGS

FIG. 1 is a perspective view for illustrating an operating face of an electronic device of an embodiment of the present invention.

FIG. 2 is a perspective view for illustrating a back of the electronic device of the embodiment.

FIG. 3 is a perspective view of a first battery which can be applied to the electronic device of the embodiment.

FIG. 4 is a perspective view for illustrating an embodiment of a battery (second battery) of the present invention to be applied to electronic devices including the electronic device of the embodiment.

FIGS. 5A-5C illustrate a process for accommodating the first battery in the electronic device in alphabetical order.

FIGS. 6A-6C illustrate a process for accommodating the second battery in the electronic device in alphabetical order.

### DETAILED DESCRIPTION

An advantage of an embodiment is to provide an electronic device configured to alternatively accommodate batteries of different sizes, and to provide a battery which can be properly used for such an electronic device.

According to an embodiment, an electronic device configured to alternatively accommodate one of a first battery and a second battery is provided. The electronic device has a housing in which a battery holder including a first space and a second space is formed. The first space is shaped so as to hold the first battery. The second space continues from the first space. The second space is narrower than the first space at an interface between the first space and the second space. The second space is shaped so that the first space and the second space can hold the second battery together. The electronic device has a contact terminal for supplying the electronic device with power from one of the first battery and the second battery. The contact terminal is provided in the first space.

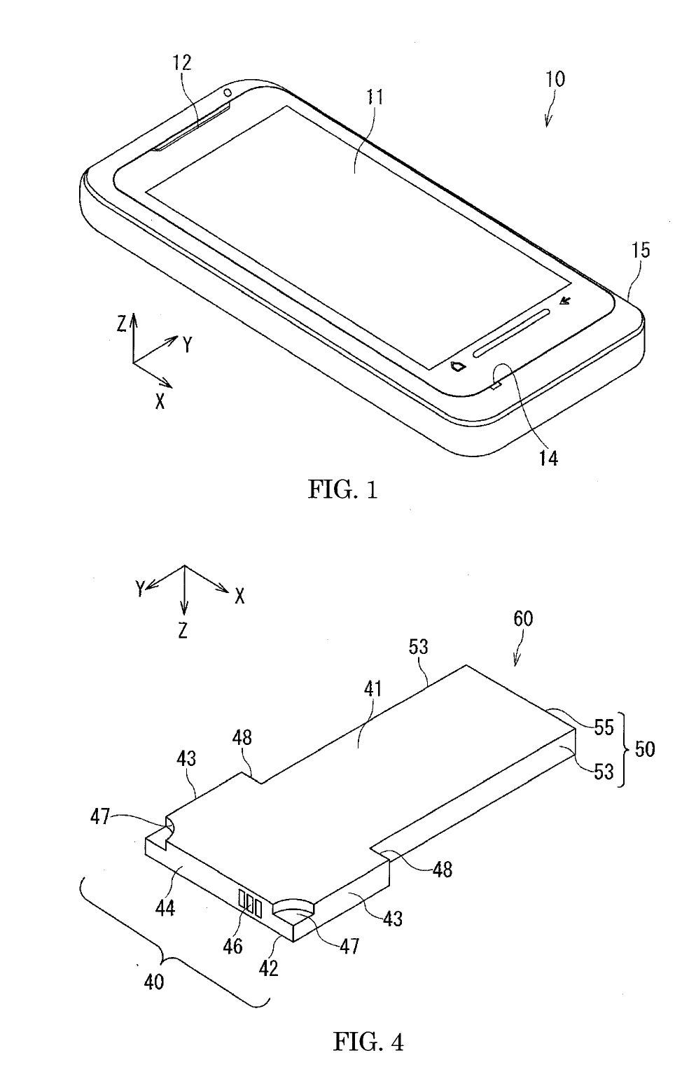

An embodiment of the present invention will be explained with reference to the drawings, as follows. As shown in FIG. 1, an electronic device 10 is provided on its operating face with a touchscreen 11 for displaying data and entering data by means of touch operations, a speaker 12 for producing voice and a microphone 14 for entering voice, which are supported by a rectangular housing 15.

The touchscreen 11 is provided with a display function for displaying screen data and an input function for entering instructions by detecting a position at which a user touches the screen by using his or her finger or an exclusive stylus. The touchscreen 11 is provided on its surface with a plurality of elements for sensing a touch operation and a transparent screen layered on top of the elements. The elements of the touchscreen 11 sense a touch operation by using a pressure-sensitive method for sensing a change of pressure or an electrostatic method for sensing an electric signal caused by static electricity, or by properly using another method.

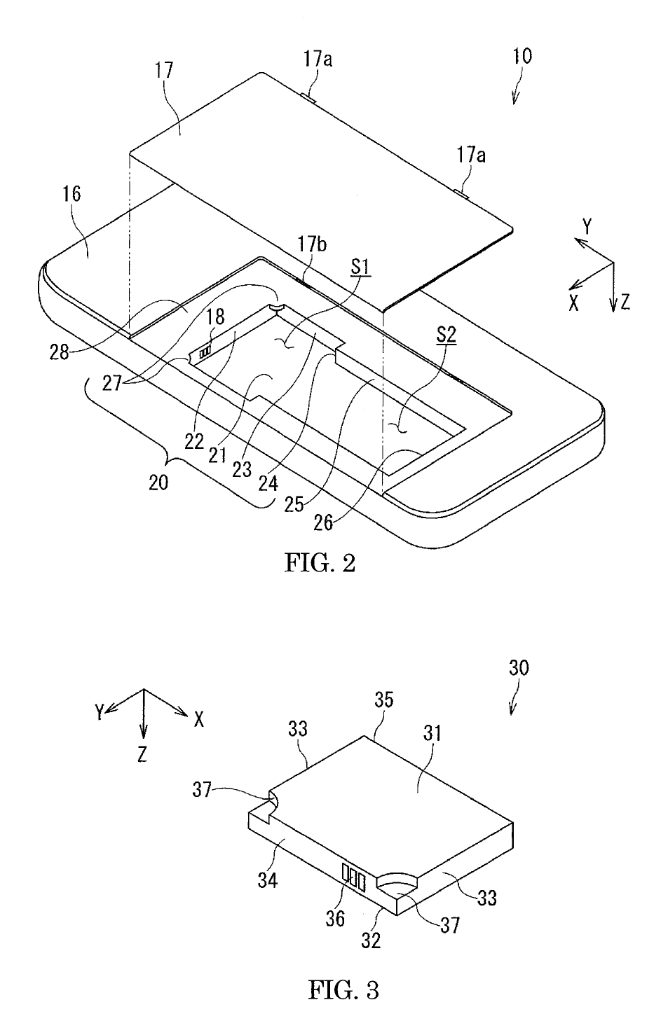

As shown in FIG. 2, the electronic device 10 is provided with a battery holder 20 on a lower level face 28 of a rear panel 16 on a back of the electronic device 10. The battery holder 20 is covered by a cover plate 17 that can be easily put on and taken off during an ordinary use of the electronic device 10. The cover plate 17 has on a side of it projections 17a which engage with a trench 17b so as to fix and integrate the plate 17 into the rear panel 16.

The battery holder 20 is formed by a first space S1 and a second space S2 continuing from the first space S1. The first space S1 is formed to hold a first battery 30 (FIG. 3). The second space S2 is formed in such a way that the first space S1 and the second space S2 hold a second battery 60 (FIG. 4) together, and that the first space S1 and the second space S2 have a base 21 in common.

The first space S1 is surrounded by an edge face 22, a pair of first guide faces 23 and a pair of first contact faces 24. The edge face 22 is formed from an end of the base 21 in the vertical direction. The first guide faces 23 are opposite each other. The first contact faces 24 are in a relative position such that they could be extended to a same plane. The second space S2 is surrounded by a pair of second guide faces 25 and a second contact face 26. The second guide faces 25 are formed from ends of the base 21 in the vertical direction and are opposite each other. The second contact face 26 has both ends crossing the second guide faces 25.

Among the above faces, the edge face 22 is provided with a contact terminal 18 for guiding driving power to the electronic device 10. Further, retainers 27 are provided above corners at which the edge face 22 and the respective ones of the paired first guide faces 23 meet, and retains the first battery 30 or the second battery contained in the battery holder 20 in the first space S1.

The contact terminal 18 is provided in such a way as to be supplied with power by either one of the first battery 30 (FIG. 3) and the second battery 60 (FIG. 4) which are alternatively contained. Further, the contact terminal 18 sticks out vertically to the edge face 22, so as to elastically press the contained first or second battery 30 or 60.

As shown in FIG. 3, the first battery 30 is shaped into a rectangular parallelepiped formed by an upper face 31, a lower face 32, a pair of side faces 33, a front 34 and a back 35. Among the above faces, the front 34 is provided with an electrode 36 which is in contact with the contact terminal 18 of the battery holder 20 (FIG. 2) for supplying driving power from the first battery 30 to the electronic device 10.

Then, a pair of cut-off portions 37 is formed on vertices where the upper face 31, the side faces 33 and the front 34 meet. The cut-off portions 37 are in contact with the retainers 27 of the battery holder 20 (FIG. 2), and prevents the first battery 30 from dropping out of the first space S1.

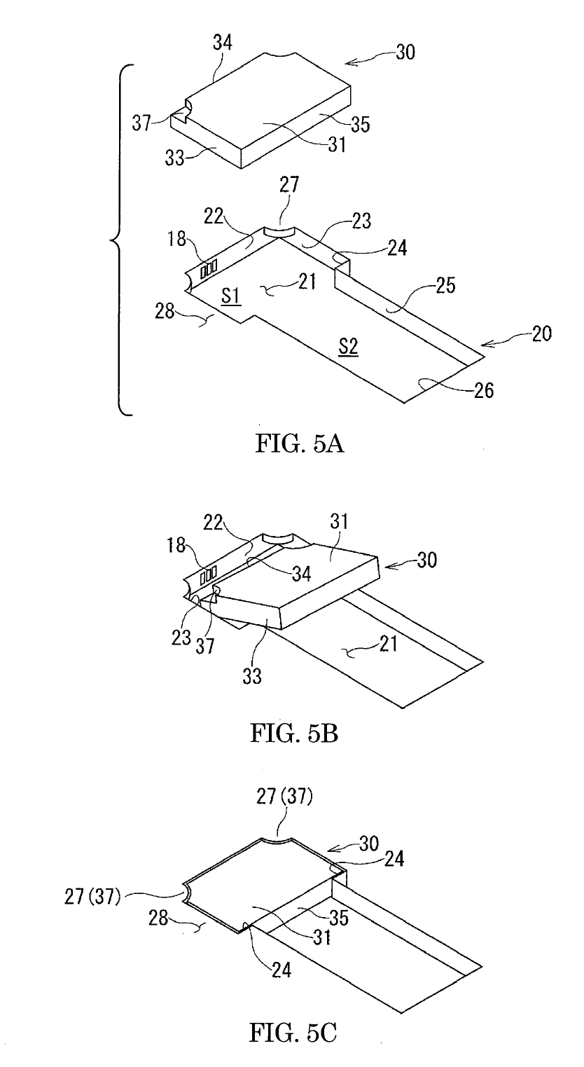

FIGS. 5A-5C illustrate a process for accommodating the first battery 30 in the battery holder 20. As shown in FIG. 5A, first, put the first battery 30 above the first space S1 of the battery holder 20.

As shown in FIG. 5B, then, guide the paired side faces 33 of the first battery 30 individually to the paired first guide faces 23 of the battery holder 20. Then, slide a lower side on the base 21 of the battery holder 20 while tilting the upper face 31 of the first battery 30, and move the front 34 of the first battery 30 toward the edge face 22 of the battery holder 20. Then, upon engaging the cut-off portions 37 of the first battery 30 with the retainers 27 of the battery holder 20, lay horizontally the first battery 30 having been tilted. At this time, after the front 34 gets in contact with the contact terminal 18, push the first battery 30 further while resisting the elastic force of the contact terminal 18, so as to fit the first battery 30 into the first space S1.

As shown in FIG. 5C, then, the first battery 30 is contained integrally in the first space S1 of the battery holder 20. At this time, the back 35 of the first battery 30 is in contact with the first side faces 24 of the first space S1. Further, as the cut-off portions 37 are engaged with the retainers 27 of the battery holder 20, the first battery 30 is steadily held without dropping out of the first space S1 even if affected by inertial force. As the second space is narrower than the first space at an interface between the first space and the second space, the first battery can be held in the first space while the second space is left empty.

In this state, then, the lower face 32 of the first battery 30 is in contact with the base 21 of the battery holder 20, and the upper face 31 is leveled off with the lower level face 28 on the back of the electronic device 10. Fit the cover plate 17 (FIG. 2) to the battery holder 20 in this state, so that the first battery 30 is pressed against the battery holder 20 and does not slip out of the battery holder 20 while the electronic device 20 is being used.

As shown in FIG. 4, the second battery 60 includes a wider portion 40 and a body portion 50 having an upper face 41 and a lower face 42 in common. The wider portion 40 has the upper face 41, the lower face 42, a pair of first side faces 43, a front 44 and protruding faces 48. The body portion 50 has a pair of second side faces 53 and a top face 55. Concerning the second battery 60, each of the first sides 43 is linked with each of the second side faces 53 via each of the protruding faces 48 to form a step.

Among the above faces, the front 44 is provided with an electrode 46 which is in contact with the contact terminal 18 of the battery holder 20 (FIG. 2) so as to supply the electronic device 20 with driving power from the second battery 60. Then, a pair of cut-off portions 47 is formed on vertices where the upper face 41, the side faces 43 and the front 44 meet. The cut-off portions 47 are in contact with the retainers 27 of the battery holder 20 (FIG. 2), and prevents the second battery 60 from dropping out.

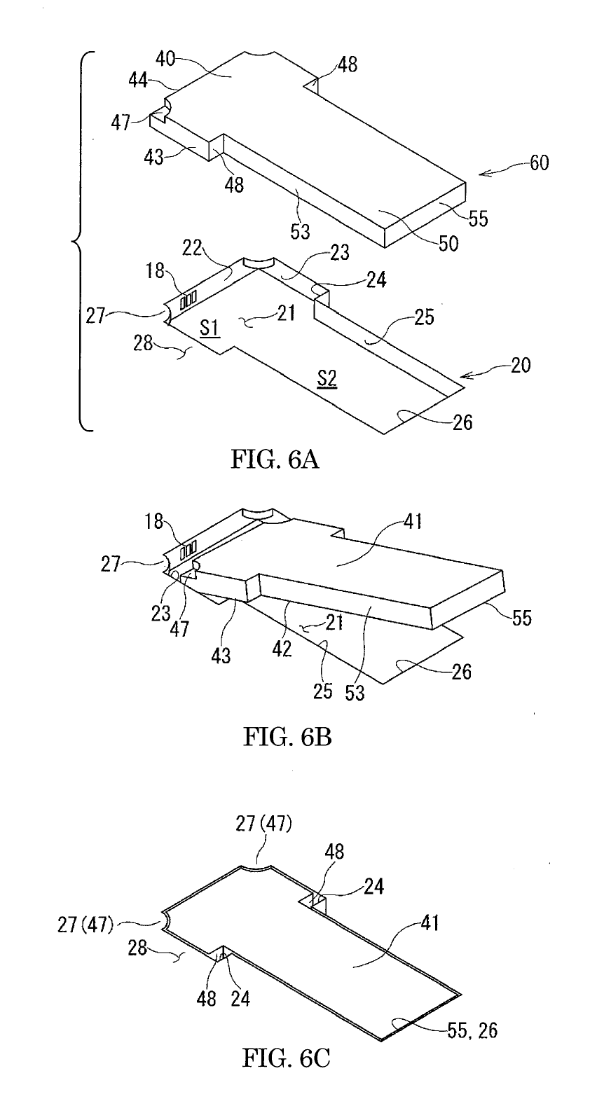

FIGS. 6A-6C illustrate a process for accommodating the second battery 60 in the battery holder 20. As shown in FIG. 6A, first, put the second battery 60 above the first space S1 and the second space 60 of the battery holder 20.

As shown in FIG. 6B, then, guide the paired first side faces 43 of the wider portion 40 of the second battery 60 individually to the paired first guide faces 23 of the battery holder 20. Then, slide a lower side of the wider portion 40 on the base 21 of the battery holder 20 while tilting the upper face 41 of the second battery 60, and move the front 44 of the second battery 60 close to the edge face 22 of the battery holder 20. Then, upon engaging the cut-off portions 47 of the second battery 60 with the retainers 27 of the battery holder 20, lay horizontally the second battery 60 having been tilted.

At this time, after the front 44 gets in contact with the contact terminal 18, push the second battery 60 further while resisting the elastic force of the contact terminal 18, so as to fit the wider portion 40 into the first space S1. Further, in succession, guide the paired second side faces 53 of the body portion 50 of the second battery 60 individually to the paired second guide faces 25 of the battery holder 20, so as to fit the body portion 50 into the second space S2.

As shown in FIG. 6C, then, the second battery 60 is contained integrally in the first space S1 and the second space S2 of the battery holder 20. At this time, the top face 55 of the body portion 50 of the second battery 60 is in contact with the second contact face 26 of the second space S2.

Incidentally, a clearance is provided between each of the protruding faces 48 of the second battery 60 and each of the first contact faces 24 of the battery holder 20, so that most of the elastic force of the contact terminal 18 is provided to the second contact face of 26 of the second space S2. Further, as the cut-off portions 47 are engaged with the retainers 27 of the battery holder 20, the second battery 60 is steadily held without dropping out even if affected by inertial force.

In this state, then, the lower face 42 of the second battery 60 is in contact with the base 21 of the battery holder 20, and the upper face 41 is leveled off with the lower level face 28 on the back of the electronic device 10. Fit the cover plate 17 (FIG. 2) to the battery holder 20 in this state, so that the second battery 60 is pressed against the battery holder 20 and does not slip out of the battery holder 20 while the electronic device 20 is being used.

The present invention is not limited to the embodiment described above, and can be properly modified so as to be implemented within a scope of common technological thought. Although being a mobile device having a touch panel as explained as to the embodiment above, e.g., the electronic device 10 is not limited to the above and can be a mobile phone, a PHS (Personal Handyphone System), a PDA (Personal Digital Assistant), an MID (Mobile Internet Device), a portable music player, a portable video camera, a portable game machine, other data communication terminal, a home appliance or whatever configured to be supplied with power from a battery.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An electronic device configured to alternatively accommodate one of a first battery and a second battery, comprising:
a housing in which a battery holder including a first space and a second space is formed, the first space being shaped so as to hold the first battery, the second space continuing from the first space, the second space being narrower than the first space at an interface between the first space and the second space, the second space being shaped so that the first space and the second space can hold the second battery together; and
a contact terminal for supplying the electronic device with power from one of the first battery and the second battery, the contact terminal being provided in the first space.

2. The electronic device according to claim 1, wherein the contact terminal is configured to provide one of the first battery and the second battery accommodated in the battery holder with elastic force.

3. The electronic device according to claim 1, wherein a retainer is provided around the first space for retaining one of the first battery and the second battery in the first space.

4. An electronic device, comprising:
a first space shaped so as to hold a first battery;
a second space expanded from the first space, the second space being shaped so that the first space and the second space can hold a second battery together; and
a contact terminal configured to be supplied with power from the first battery and the second battery which are alternatively accommodated.

5. The electronic device according to claim 4, further comprising:
a first contact face formed in the first space, the first battery being in contact with the first contact face upon being provided with elastic force by the contact terminal; and
a second contact face formed in the second space, the second battery being in contact with the second contact face upon being provided with elastic force by the contact terminal.

6. The electronic device according to claim 4, wherein the first space is provided with a retainer for retaining the first battery or the second battery.

7. A battery which can be used for an electronic device, comprising:
a wider portion configured to be guided into a first space of the electronic device, the wider portion being provided with an electrode for supplying the electronic device with power upon the electrode being in contact with a contact terminal provided in the first space; and
a body portion configured to be guided into a second space of the electronic device, the second space being expanded from the first space, the body portion configured to be in contact with a contact face of the second space owing to elastic force provided from the contact terminal to the electrode.

8. The battery according to claim 7, wherein the wider portion is provided with a cut-off portion to be engaged in the first space.
